(19) United States
(12) Patent Application Publication
(10) Pub. No.: US 2006/0051965 A1
(43) Pub. Date: Mar. 9, 2006

(54) Methods of etching photoresist on substrates

(75) Inventors: Erik A. Edelberg, Castro Valley, CA (US); Robert P. Chebi, San Carlos, CA (US); Alex F. Panchula, Menlo Park, CA (US)

Correspondence Address: BUCHANAN INGERSOLL PC;(INCLUDING BURNS, DOANE, SWECKER & MATHIS), POST OFFICE BOX 1404, ALEXANDRIA, VA, 22313-1404, US

(73) Assignee: Lam Research Corporation

(21) Appl. No.: 10/934,697

(22) Filed: Sep. 7, 2004

(51) Int. Cl. H01L 21/461; H01L 21/302

(52) U.S. Cl. 438/706; 438/710; 438/725

(57) ABSTRACT

Methods of etching a carbon-rich layer on organic photoresist overlying an inorganic layer can utilize a process gas including a fluorine-containing gas, an oxygen-containing gas, and a hydrocarbon gas, and one or more optional components to generate a plasma effective to etch the carbon-rich layer with low removal of the inorganic layer. The carbon-rich layer can be removed in the same processing chamber, or alternatively can be removed in a different processing chamber, as used to remove the bulk photoresist.

### BACKGROUND

Plasma processing apparatuses are used for processes including plasma etching, physical vapor deposition, chemical vapor deposition (CVD), ion implantation, and resist removal.

Photoresist materials are used in plasma processing operations to pattern materials. Commercial photoresists are blends of polymeric and other organic and inorganic materials. A photoresist is applied onto a substrate, and radiation is passed through a patterned mask to transfer the pattern into the resist layer. The two broad classifications of photoresist are negative-working resist and positive-working resist, which produce negative and positive images, respectively. After being developed, a pattern exists in the photoresist. The patterned photoresist can be used to define features in substrates by etching, as well as to deposit materials onto, or implant materials into, substrates. Commonly-assigned U.S. Pat. Nos. 5,968,374, 6,362,110 and 6,692,649, the disclosures of which are hereby incorporated by reference, disclose plasma photoresist stripping techniques.

### SUMMARY

Methods for etching organic photoresist on substrates are provided, as are plasma etch gas compositions useful for etching organic photoresist on substrates. The methods and compositions can selectively etch photoresist relative to the substrate.

A preferred embodiment of the methods of etching organic photoresist on a substrate comprises positioning in a plasma processing chamber a substrate including an inorganic layer and an organic photoresist overlying the inorganic layer, the photoresist including a carbon-rich layer overlying bulk photoresist; supplying to the processing chamber a process gas comprising (i) a fluorine-containing gas, (ii) an oxygen-containing gas, and (iii) a hydrocarbon gas; generating a plasma from the process gas; and selectively plasma etching the carbon-rich layer relative to the inorganic layer. Optionally, an RF bias may be applied to the substrate during etching of the carbon-rich layer.

The bulk photoresist can be stripped in the same plasma processing chamber that is used to etch the carbon-rich layer. Alternatively, the bulk photoresist can be stripped in an ashing chamber. The bulk photoresist preferably is stripped using a different chemistry than used to remove the carbon-rich layer.

A preferred embodiment of the plasma etch gas composition useful for etching an organic photoresist on a substrate comprises (i) a fluorine-containing gas, (ii) an oxygen-containing gas, and (iii) a hydrocarbon gas.

### BRIEF DESCRIPTION OF THE DRAWINGS

FIG. 1 schematically illustrates a process for removing an ion-implanted, carbon-rich layer formed on photoresist overlying a silicon substrate using a plasma generated from 100% O₂ or H₂O vapor with RF bias applied to the substrate.

FIG. 2 is a scanning electron microscope (SEM) micrograph showing typical residue present on the surface of a post-implant substrate after etching an organic photoresist in an RF-biased plasma source using 100% O₂ or H₂O vapor.

FIG. 3 depicts an exemplary inductively-coupled plasma reactor which can be used to perform embodiments of the methods of removing photoresist from substrates.

FIG. 4 depicts an exemplary parallel-plate plasma reactor which can be used to perform embodiments of the methods of removing photoresist from substrates.

FIG. 5 schematically illustrates a process for removing an ion-implanted, carbon-rich layer formed on organic photoresist overlying a silicon substrate using a plasma generated from a process gas containing CF₄, O₂, and CH₄ with RF bias applied to the substrate.

FIG. 6 is an SEM micrograph showing the surface of an implanted wafer after photoresist removal in an RF-biased plasma source using a process gas containing CF₄, O₂, and CH₄.

FIGS. 7A, 7B, and 7C are based on the same data; FIG. 7A is a ternary plot of oxide loss in Å as a function of the volume percent of CF₄, O₂, and CH₄ flowing into the processing chamber; FIG. 7B is a plot of oxide loss in Å as a function of the volume percent of CH₄ in the process gas; and FIG. 7C is a plot of oxide loss in Å as a function of the ratio of CH₄ to CF₄ in the process gas.

### DETAILED DESCRIPTION

In integrated circuit (IC) manufacturing processes that utilize ion implantation, shrinking device geometries, increased ion implantation energies and doses, and new materials make it increasingly difficult to produce residue-free devices. Residues remaining from etching and ashing processes can produce undesirable electrical effects and corrosion that reduce product yields. See E. Pavel, “Combining Microwave Downstream and RF Plasma Technology for Etch and Clean Applications,” 196^{th} Meeting of the Electrochemical Society, (October, 1999).

In plasma processing techniques, such as plasma etching and reactive ion etching (RIE), and in ion implantation, photoresist is applied onto a substrate to protect selected regions of the substrate from being exposed to ions and free radicals. Organic polymer compositions have been formulated for such resist applications.

Photoresists are removed, or “stripped,” from the underlying substrate after the substrate has been processed by etching, ion implantation, or the like. It is desirable that the photoresist stripping process leave the substrate surface as clean as possible, desirably without any residual polymer film or resist material. Wet and dry stripping techniques can be used to remove photoresist. Wet stripping techniques use solutions containing organic solvents or acids. Dry stripping (or “ashing”) techniques use an oxygen plasma for photoresist removal.

Ion implantation fabrication techniques are used to dope regions of a substrate with impurities to change the electrical properties of the substrate. Ion implantation can be used as a source of doping atoms, or to introduce regions of different composition in a substrate. During ion implantation, ions are accelerated at a sufficiently high voltage to penetrate the substrate surface to a desired depth. Increasing the accelerating voltage increases the depth of the concentration peak of the impurities.

Regions of the substrate at which implantation is not desired are protected with photoresist. However, the photoresist is modified during implantation, and is rendered more difficult to remove after implantation than a normal (non-implanted) photoresist. Particularly, implanted ions damage regions of the photoresist, thereby breaking near-surface C—H bonds and forming carbon-carbon single and double bonds. The resulting tough, carbon-rich or “carbonized” layer (or “skin” or “crust”) of cross-linked, implanted photoresist encapsulates the distinct underlying bulk photoresist. The thickness of the carbon-rich layer is a function of the implant species, voltage, dose and current. The carbon-rich layer typically has a thickness of from about 200 Å to about 2000 Å. See, A. Kirkpatrick et al., “Eliminating heavily implanted resist in sub-0.25-μm devices,” MICRO, 71 (July/August 1998). According to E. Pavel, as implant doses and energies increase, implanted photoresist can become increasingly more difficult to remove.

Carbon-rich layers can also be formed in organic photoresist during plasma processing techniques, other than ion-implantation techniques, in which ion bombardment of the photoresist also occurs.

Oxygen plasma ashing techniques can remove the carbon-rich layer, but only at a slow rate of about 500 Å/min or less. The etching mechanism of these techniques is the reaction of oxygen radicals with hydrocarbons in the photoresist to produce H₂O and CO₂.

It has been determined that an RF bias can be applied to the substrate to enhance the removal rate of the cross-linked layer. The applied RF bias provides energy to the carbon-rich layer, which breaks carbon single bonds and thereby enhances reactions with oxygen radicals.

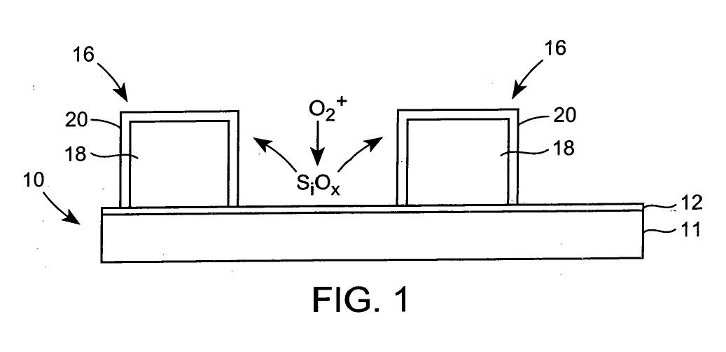

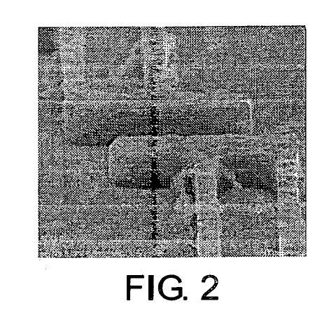

However, it has also been determined that applying an RF bias to the substrate to enhance photoresist removal can also produce undesired effects. FIG. 1 schematically depicts a process of removing organic photoresist from an ion-implanted substrate 10. The substrate 10 includes silicon 11 that is ion implanted and a thin overlying inorganic layer 12 (e.g., a silicon-containing layer, such as SiOₓ). The inorganic layer 12 may be a silicon oxide layer that is formed by CVD, thermally grown, or may be a native oxide, and typically has a thickness of less than or equal to 20 Å. A photoresist 16 applied over the inorganic layer 12 includes bulk photoresist 18, and an overlying carbon-rich layer 20 formed by the ion-implantation process. The features (contacts, vias, trenches, etc.) defined by the photoresist 16 are typically about 0.25 μm or less in width on the substrate 10. In an RF biased system, energetic O₂⁺ ions can cause sputtering of the inorganic layer 12. Sputtering of the inorganic layer 12 is undesirable because for typical process specifications the maximum amount of inorganic material (e.g., oxide) loss during the removal of the carbon-rich layer 20 and the bulk photoresist 18 is less than about 2 Å. The carbon-rich layer 20 can typically have a thickness of from about 200 to about 2000 Å, and the bulk photoresist 18 can typically have a thickness of about several thousand angstroms. In addition, sputtered inorganic material can re-deposit on the substrate and on the photoresist, resulting in organic and inorganic residue being present on the substrate after cleaning. FIG. 2 is a scanning electron microscope (SEM) micrograph showing residue present on the surface of a post-implant wafer at regions at which photoresist is present on the substrate after photoresist ashing in an RF-biased plasma source using 100% O₂ or H₂O vapor.

Another undesirable effect of applying a bias voltage to the substrate for carbon-rich layer removal is that oxygen ions of the plasma may have sufficiently high energy to penetrate the thin inorganic layer and oxidize the underlying silicon.

In light of the above-described findings, it has been determined that process gases including a fluorine-containing gas, an oxygen-containing gas, and a hydrocarbon gas can be used in organic photoresist etching processes to control, and preferably to eliminate, sputtering and re-deposition, as well as growth, of inorganic material. The inorganic material can be, for example, a silicon-containing material (e.g., Si, SiOₓ [e.g. SiO₂], SiₓN_{y} [e.g., Si₃N₄], SiₓO_{y}N_{z}, HfSiₓO_{y} and the like), and HfO. The photoresist can be present on various semiconductor substrate materials such as wafers including, e.g., silicon, SiO₂, Si₃N₄, and the like.

Exemplary fluorine-containing gases suitable for inclusion in the process gas include CF₄, SF₆, and NF₃. More particularly, a preferred process gas for removing the carbon-rich overlying bulk photoresist includes CF₄, O₂, and CH₄. The process gas can also include one or more other optional gases, such as N₂. Also, the process gas can include one or more inert carrier gases, such as Ar, He, or the like.

The process gas preferably comprises, by volume, up to about 50% of the fluorine-containing gas, up to about 50% of the hydrocarbon gas, and at least 50% of the oxygen-containing gas. More preferably, the gas mixture comprises, by volume, up to about 20% of the fluorine-containing gas, from about 10% to about 50% of the hydrocarbon gas, and from about 50% to about 90% of the oxygen-containing gas.

Hydrogen in the process gas softens the carbon-rich layer, making this layer easier to remove by etching.

Other gases that can remove the carbon-rich layer include CF₄ and CHF₃. However, if CF₄ is used, it is preferably combined with CH₄ to provide desired selectivity with respect to the inorganic layer (e.g., to an SiOₓ layer).

The photoresist can be any suitable organic polymer composition. For example, the photoresist composition can include a resin of the Novolak class, a polystyrene component, or the like.

To remove the organic photoresist, the process gas including fluorine-containing gas, oxygen-containing gas, and hydrocarbon gas, is energized to generate a plasma.

The plasma is preferably generated from the process gas by applying radio frequency (RF) to an electrically conductive coil outside of the plasma processing chamber. The wafer is preferably placed in the plasma generation region. In a preferred embodiment, the coil is a planar coil and the wafer is parallel to the plane of the coil.

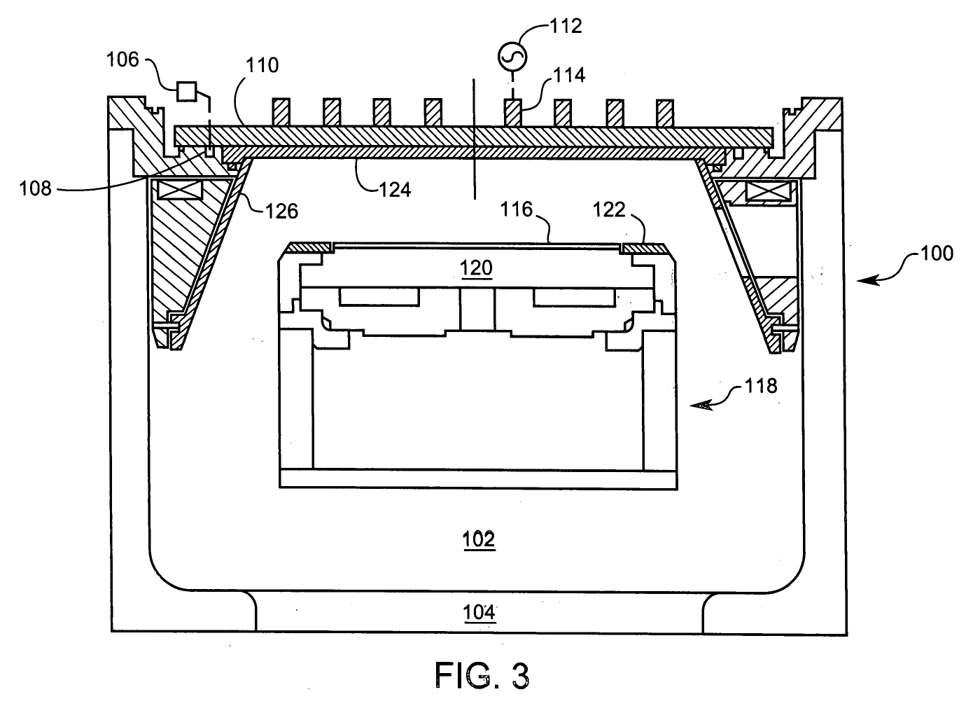

The plasma reactor is preferably an inductively coupled plasma reactor, more preferably a high density TCP™ reactor available from Lam Research Corporation, the assignee of the present application. Embodiments of the methods of removing photoresist from substrates, such as 300 mm and 200 mm substrates, can be performed in an inductively-coupled plasma reactor, such as the reactor 100 shown in FIG. 3. The reactor 100 includes an interior 102 maintained at a desired vacuum pressure by a vacuum pump connected to an outlet 104. Process gas can be supplied to a showerhead arrangement by supplying gas from a gas supply 106 to a plenum 108 extending around the underside of a dielectric window 110. A high density plasma can be generated in the interior 102 by supplying RF energy from an RF source 112 to an external RF antenna 114, such as a planar spiral coil having one or more turns disposed outside the dielectric window 110 on top of the reactor 100.

A substrate 116, such as a semiconductor wafer, is supported within the interior 102 of the reactor 100 on a substrate support 118. The substrate support 118 can include a chucking apparatus, such as an electrostatic chuck 120, and the substrate 116 can be surrounded by a dielectric focus ring 122. The chuck 120 can include an RF biasing electrode for applying an RF bias to the substrate during plasma processing of the substrate 116. The process gas supplied by the gas supply 106 can flow through channels between the dielectric window 110 and an underlying gas distribution plate 124 and enter the interior 102 through gas outlets in the plate 124. Alternatively, the gas can be supplied by one or more gas injectors extending through the window. See, for example, commonly-assigned U.S. Pat. No. 6,230,651. The reactor can also include a liner 126 extending from the plate 124.

An exemplary plasma reactor that can be used for generating plasma is the 2300 TCP™ reactor available from Lam Research Corporation. Typical operation conditions for the plasma reactor are as follows: from about 400 to about 1400 watts inductive power applied to upper electrode (coil), reaction chamber pressure of from about 15 to about 60 mTorr, and a total process gas flow rate of from about 200 to about 600 sccm.

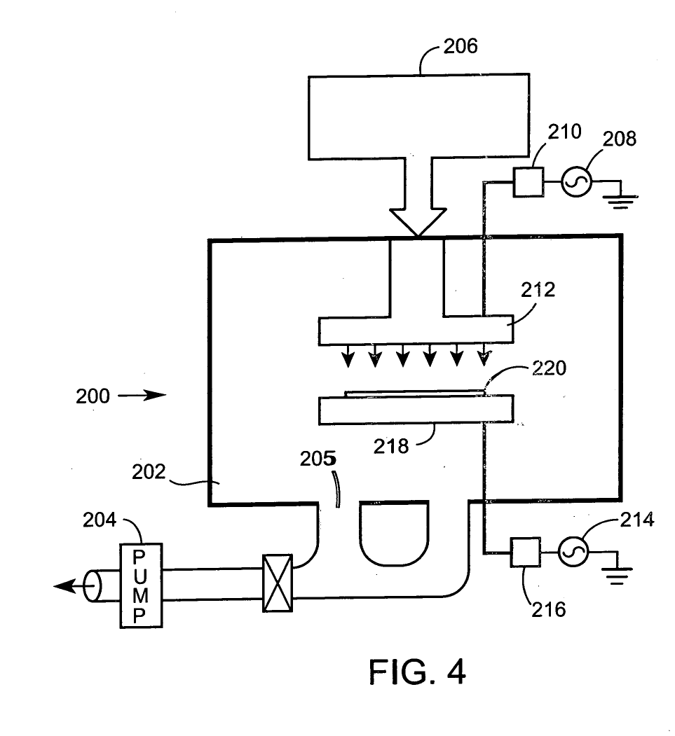

Embodiments of the methods of removing photoresist from substrates can also be performed in a dual frequency, parallel-plate plasma reactor, such as reactor 200 shown in FIG. 4. Exemplary dual frequency reactors include the Exelan™ reactors available from Lam Research Corporation. Details of dual frequency reactors can be found in commonly-assigned U.S. Pat. No. 6,391,787, the disclosure of which is hereby incorporated by reference. The reactor 200 includes an interior 202 maintained at a desired vacuum pressure by a vacuum pump 204 connected to an outlet 205 in a wall of the reactor. Process gas can be supplied to a showerhead electrode 212 by supplying gas from a gas supply 206. A medium-density plasma can be generated in the interior 202 by supplying RF energy from RF source 208, 210 and RF source 214, 216 to the showerhead electrode 212, and to a bottom electrode of a chuck 220 of a substrate support 218. Alternatively, the showerhead electrode 212 can be electrically grounded, and RF energy at two different frequencies can be supplied to the bottom electrode. Other capacitively-coupled etch reactors can also be used, such as those having RF power supplied only to a showerhead or upper electrode, or only to a bottom electrode. See, for example, commonly-assigned U.S. Pat. Nos. 6,518,174 and 6,770,166, the disclosures of which are hereby incorporated by reference.

During removal of the carbon-rich layer, the substrate is preferably maintained at a sufficiently low temperature on a substrate support to prevent rupturing of the layer. For example, a carbon-rich layer may rupture when solvents in the photoresist composition are volatilized by heating, producing particles that may deposit on the substrate. To avoid such rupturing of the carbon-rich layer, the substrate is preferably maintained at a temperature of less than about 150° C., and more preferably from about 20 to about 75° C., and a chamber pressure of less than about 500 mTorr during etching of the carbon-rich layer.

During etching of the carbon-rich layer, RF bias is preferably applied to the substrate with a bias electrode provided in the substrate support on which the substrate is supported. The RF bias is preferably capacitive. The applied RF bias and RF power used to generate the plasma preferably are independently controllable to independently control ion energy and ion flux, respectively. The RF bias accelerates ions in the plasma and adds energy to the substrate, which increases the removal rate of the carbon-rich layer. The RF bias voltage applied to the substrate is preferably less than about 100 volts (with respect to ground), more preferably less than about 20 volts. It has been unexpectedly determined that the combined use of fluorine in the process gas and an applied RF bias to the substrate is effective to remove the carbon-rich layer at a sufficiently high rate while also providing high selectivity to inorganic material (e.g., oxide) present on the substrate. It has further been determined that at a given volume percentage (e.g., flow rate of 5 to 50 sccm fluorine-containing gas) of the fluorine-containing gas included in the process gas, the RF bias can be maintained at a low level that reduces the inorganic material removal rate from the substrate during etching of the carbon-rich layer.

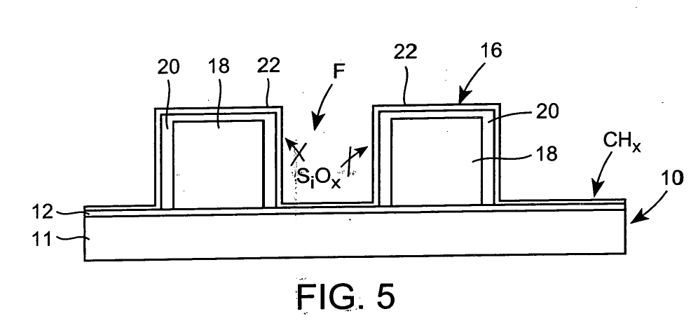

Referring to FIG. 5, it has been determined that a process gas including a fluorine-containing gas, an oxygen-containing gas, and a hydrocarbon gas can etch the carbon-rich layer while minimizing sputtering of the inorganic layer 12 (e.g., an oxide layer) and thus reduce or avoid re-deposition of sputtered inorganic material on the substrate. Fluorine can also contribute to the removal of inorganic materials that may be in or on the photoresist.

Hydrogen in the process gas used to etch the carbon-rich layer increases the etch rate of the carbon-rich layer by reacting with cross-linked carbon. It is believed that fluorine may also enhance the carbon-rich layer etch rate.

The addition of CHₓ species to the process gas used to etch the carbon-rich layer causes a passivating layer 22 to form on the oxide layer 12 and the photoresist 16 (see FIG. 5), which reduces the amount of ion-induced oxide growth and oxide sputtering.

If a single source for both fluorine and CHₓ passivation is used, such as CH₃F, carbon-rich layer removal and substrate passivation cannot be independently controlled. It has been discovered that by separating the fluorine source and the CHₓ passivation source, i.e., by providing a process gas including a fluorine-containing gas and a hydrocarbon gas, residue removal with high selectivity to the underlying substrate material can be achieved, as carbon-rich layer removal and substrate passivation can be independently controlled.

The complete removal of the carbon-rich layer 20 can be detected during the etching process by using an endpoint detection technique, which can determine the time at which the underlying bulk photoresist is exposed. The endpoint for carbon-rich layer removal is preferably determined by an optical emission technique. For example, the optical emission technique can monitor the emission from carbon monoxide (CO) at a wavelength of about 520 nm. During the removal of the carbon-rich layer, a small CO signal is produced due to the low etch rate. Once the carbon-rich layer is opened, the exposed underlying bulk photoresist is etched at a faster rate than the carbon-rich layer and, consequently, the CO concentration and the corresponding CO signal increase.

After removal of the carbon-rich layer, the underlying bulk photoresist is preferably removed using a different photoresist etch process. For example, the bulk photoresist can be removed by oxygen ashing at a higher temperature than the temperature preferably used during the carbon-rich layer etching step. For example, the substrate temperature can range from about 150° C. to about 300° C., preferably 200 to 280° C., during the bulk photoresist etching step. The chamber pressure is preferably greater than about 500 mTorr during bulk photoresist removal. Oxygen ashing also can achieve a high removal rate of the bulk photoresist. For example, an O₂/N₂ plasma can remove the bulk photoresist at a rate of from about 4 to about 6 microns/min. An optional over-ash step can also be used. Volatile solvents in the photoresist can be exhausted from the plasma processing chamber as the photoresist is ashed.

The bulk photoresist is preferably removed in the same chamber or a different chamber using a plasma generated upstream from the substrate. However, the bulk photoresist removal step can be performed in the same processing chamber that is used to etch the carbon-rich layer. Alternatively, the bulk photoresist can be removed by etching in a different processing chamber. That is, the substrate can be removed from the processing chamber after etching the carbon-rich layer, and placed in a different processing chamber to etch the bulk photoresist. Using different processing chambers can obviate changing gas chemistries and/or the substrate temperature during removal of the carbon-rich layer and ashing, respectively.

Exemplary process conditions for removing the carbon-rich layer on a 300 mm wafer are as follows: chamber pressure of about 10-50 mTorr, preferably 30 mTorr, power applied to upper electrode (coil) of about 400-1500 Watts, preferably 1200 Watts, power applied to bias electrode of about 2-10 Watts, preferably 5 Watts, gas flow rates of about 5-50 sccm for the fluorine-containing gas, about 20-200 sccm for the hydrocarbon gas, and about 300-500 sccm for the oxygen-containing gas, and wafer temperature of below 50° C., preferably about 20° C.

If the power applied to upper electrode (coil) is too high, passivation may be lost. It is desirable that any residue generated during removal of the carbon-rich layer is soluble in deionized water, thereby minimizing the need for wet stripping techniques. It has been discovered that when the carbon-rich layer etch is carried out at higher temperatures, however, wet stripping techniques may be necessary. The flow rate of the fluorine-containing gas and/or the hydrocarbon gas may be adjusted to achieve selective etching of the carbon-rich layer relative to the inorganic layer.

Exemplary process conditions for removing the remaining bulk photoresist in a downstream plasma strip chamber are as follows: chamber pressure of about 1000 mTorr, about 2500 Watts of power applied to the plasma source, total process gas flow rate of about 4400 sccm, and substrate temperature of about 220° C.

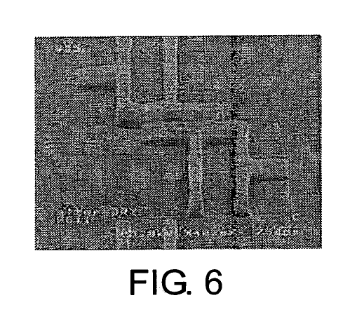

FIG. 6 shows an SEM micrograph taken of a substrate surface after performing a photoresist removal process according to a preferred embodiment. The etching process included removing the carbon-rich layer formed on the bulk photoresist using a process gas including CH₄, O₂, and CF₄ with RF bias applied to the substrate, and then removing the underlying bulk photoresist using a standard downstream strip process. As shown in FIG. 6, the photoresist was completely removed and no detectable post-etch residue is present on the wafer.

### EXAMPLES

Silicon wafers were ion implanted to produce a carbon-rich layer on underlying bulk photoresist. The Table below shows the etch rates that were determined for silicon oxide and bulk photoresist at different ratios of CH₄ to CF₄ (on a volume percent basis) in an oxygen-containing process gas, which was used to generate plasma to remove the carbon-rich layer. During stripping of the carbon-rich layer, an RF bias at a power level of 5 Watts was applied to the substrate.

The bulk photoresist etch rate was estimated by placing a non-implanted organic photoresist having a known thickness in a processing chamber and partially stripping the photoresist. As bulk photoresist is also non-implanted material, the calculated bulk photoresist etch rate approximates the etch rate of bulk photoresist underlying an implanted carbon-rich layer.

TABLE

| CH4:CF4 | Bulk Photoresist | Oxide |
|---|---|---|
| Ratio | Etch rate (Å/min) | Etch rate (Å/min) |
| 2:1 | 3063 | 0.023 |
| 3:1 | 3492 | 0.026 |
| 10:1 | 2663 | <0.010 |

The test results show that the bulk photoresist and oxide etch rates both increase with a small increase in the ratio of CH₄ to CF₄, but decrease with an increased ratio of CH₄ to CF₄. The test results demonstrate the existence of a process regime within which CH₄ passivates and protects the SiOₓ surface from chemical and/or physical attack. The oxide etch rate increases with an increasing ratio of CH₄ to CF₄ up to a ratio of CH₄ to CF₄ at which passivation of the inorganic layer is sufficiently large to decrease the etch rate of the inorganic layer. While not wishing to be bound to any particular theory, the enhanced photoresist etch rate is believed to be due to the presence of both H and F radicals in the plasma.

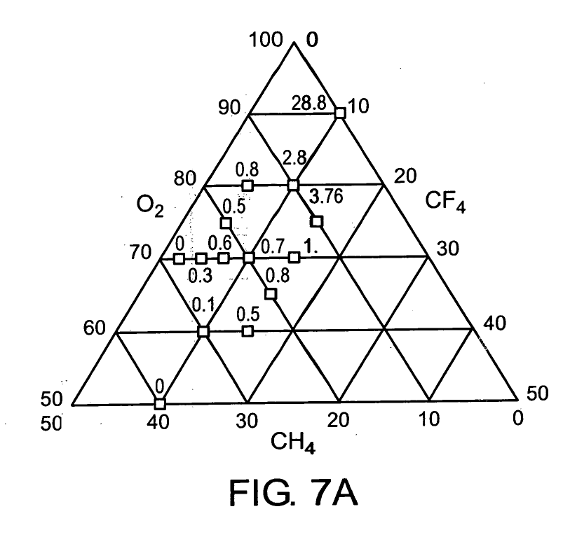

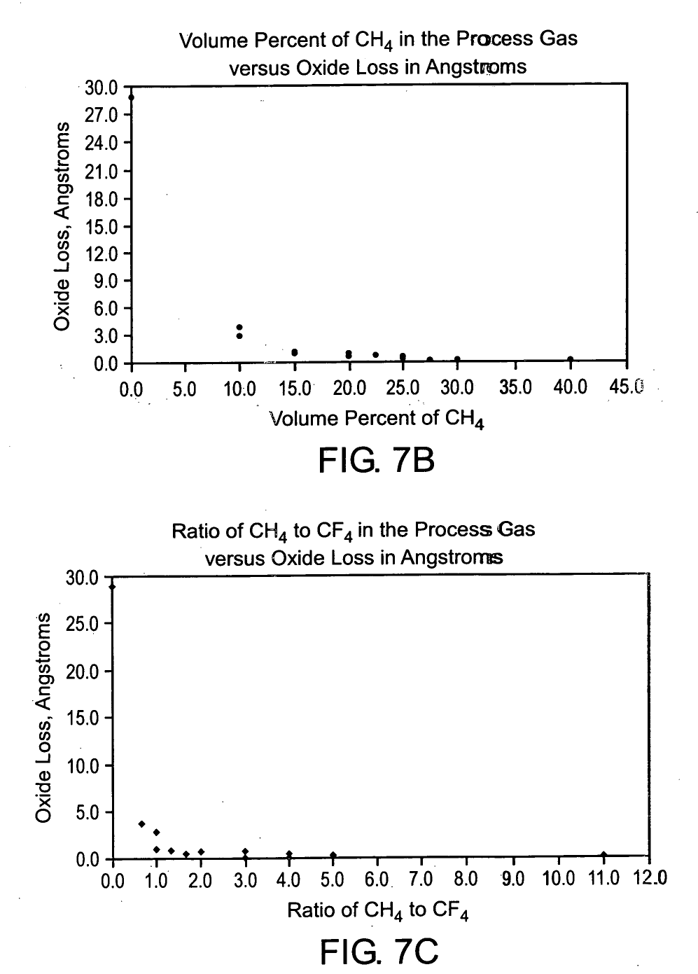

FIG. 7A is a ternary plot of O₂, CF₄ and CH₄ flow rates (50 to 100% O₂, 0 to 50% CH₄ and 0 to 50% CF₄ flow rates) versus oxide loss in Angstroms (oxide loss shown in numerical values adjacent open boxes, e.g., for 90% O₂ and 10% CF₄ the oxide loss is 28.8 Å whereas for 80% O₂, 10% CF₄ and 10% CH₄ the oxide loss is 1.8 Å). As can be seen from FIGS. 7A and 7B, addition of CH₄ to the process gas reduces oxide loss, through passivation of the oxide surface. As can be seen from FIGS. 7A and 7C, a ratio of CH₄ to CF₄ of greater than 1:1 reduces oxide loss, again through passivation of the oxide surface. Accordingly, as can be seen from FIGS. 7A and 7C and the above Table, a preferred ratio of hydrocarbon gas to fluorine-containing gas is from 1:1 to 10:1.

For comparison, gas mixtures containing 10% CF₄ (balance O₂), and 10% CHF₃ (balance O₂), were used to generate a plasma and remove the carbon-rich layer on bulk photoresist from ion-implanted silicon wafers. The oxide etch rate for the gas mixture containing CF₄ was 27 Å/min, and the oxide etch rate for the gas mixture containing CHF₃ was 15 Å/min. These oxide etch rates are too high for photoresist removal processes that have stringent maximum oxide removal specifications, such as those having a maximum oxide etch rate of about 5 Å/min, and especially those having a maximum oxide etch rate of less than about 2 Å/min.

It will be apparent to those skilled in the art that various changes and modifications can be made, and equivalents employed, to the foregoing detailed description with reference to specific embodiments thereof, without departing from the scope of the appended claims.

What is claimed is:

1. A method of etching an organic photoresist on a substrate, comprising:
positioning a substrate in a plasma processing chamber of a plasma reactor, the substrate including an inorganic layer and an organic photoresist overlying the inorganic layer, the photoresist including a carbon-rich layer overlying bulk photoresist;
supplying a process gas to the plasma processing chamber, the process gas comprising (i) a fluorine-containing gas, (ii) an oxygen-containing gas, and (iii) a hydrocarbon gas;
generating a plasma from the process gas; and
selectively plasma etching the carbon-rich layer relative to the inorganic layer.

2. The method of claim 1, wherein the process gas comprises, by volume, (i) up to about 20% of the fluorine-containing gas, (ii) from about 10% to about 50% of the hydrocarbon gas; and (iii) from about 50% to about 90% of the oxygen-containing gas.

3. The method of claim 2, wherein a ratio of the volume of the hydrocarbon gas to the volume of the fluorine-containing gas is between 1:1 and 10:1.

4. The method of claim 2, wherein the process gas is supplied at flow rates of (i) 5-50 sccm of the fluorine-containing gas, (ii) 20-200 sccm of the hydrocarbon gas, and (iii) 300-500 sccm of the oxygen-containing gas.

5. The method of claim 1, wherein an RF bias is applied to the substrate and carbon single bonds in the carbon-rich layer are broken by applying the RF bias.

6. The method of claim 1, wherein the fluorine-containing gas is selected from the group consisting of CF₄, SF₆, and NF₃.

7. The method of claim 6, wherein the fluorine-containing gas is CF₄, the oxygen-containing gas is O₂ and/or the hydrogen carbon gas is CH₄.

8. The method of claim 1, wherein the process gas includes hydrogen in an amount effective to soften the carbon-rich layer.

9. The method of claim 1, wherein the plasma is a medium density plasma and the processing chamber is at a pressure of 15 to 60 mTorr.

10. The method of claim 1, wherein the plasma is a high-density plasma.

11. The method of claim 1, further comprising applying an RF bias to the substrate during etching of the carbon-rich layer.

12. The method of claim 1, wherein the carbon-rich layer is an ion-implanted layer having a thickness of 200 to 2000 Å.

13. The method of claim 1, wherein the inorganic layer is a silicon-containing layer and the hydrocarbon gas is present in an amount effective to passivate the silicon-containing layer.

14. The method of claim 13, wherein the silicon-containing layer is a silicon oxide layer.

15. The method of claim 14, wherein the silicon oxide layer is a native oxide, a thermally grown oxide, or is formed by CVD.

16. The method of claim 14, wherein the silicon oxide layer has a thickness of less than or equal to 20 Å.

17. The method of claim 1, wherein less than or equal to 2 Å of the inorganic layer is removed during etching of the carbon-rich layer.

18. The method of claim 1, wherein the substrate is maintained at a temperature of 20 to 75° C. while maintaining pressure in the chamber at less than 500 mTorr.

19. The method of claim 1, further comprising, after etching the carbon-rich layer, cleaning the substrate with deionized water or other wet clean chemistry.

20. The method of claim 1, further comprising:
after etching the carbon-rich layer, removing the substrate from the plasma processing chamber and placing the substrate in an ashing chamber;
supplying an ashing gas containing oxygen to the ashing chamber;
generating a plasma from the ashing gas; and
etching the bulk photoresist with the plasma.

21. The method of claim 1, further comprising:
after etching the carbon-rich layer, supplying an ashing gas containing oxygen to the plasma processing chamber;
generating a stripping plasma from the ashing gas; and
stripping the bulk photoresist with the stripping plasma while maintaining the substrate at 150 to 300° C. and pressure in the chamber above 500 mTorr pressure.

22. A plasma etch gas composition, useful for etching an organic photoresist on a substrate, comprising: (i) a fluorine-containing gas, (ii) an oxygen-containing gas, and (iii) a hydrocarbon gas, the fluorine-containing gas, the oxygen-containing gas and the hydrocarbon gas being present in amounts by volume such that a carbon-rich layer can be removed from an underlying organic photoresist during plasma etching of the carbon-rich layer with the etch gas.

23. The plasma etch gas composition of claim 22, wherein the process gas comprises, by volume, (i) up to about 20% of the fluorine-containing gas, (ii) from about 10% to about 50% of the hydrocarbon gas; and (iii) at least 50% of the oxygen-containing gas.

24. The plasma etch gas composition of claim 23, wherein a ratio of the volume of the hydrocarbon gas to the volume of the fluorine-containing gas is from 1:1 to 10:1.

25. The plasma etch gas composition of claim 22, wherein the fluorine-containing gas is selected from the group consisting of CF₄, SF₆, and NF₃.

26. The plasma etch gas composition of claim 25, wherein the fluorine-containing gas is CF₄.

27. The plasma etch gas composition of claim 22, wherein the oxygen-containing gas is O₂.

28. The plasma etch gas composition of claim 22, wherein the hydrocarbon gas is CH₄.

29. The plasma etch gas composition of claim 22, wherein the plasma etch gas consists of CF₄, O₂ and CH₄.
